(19) United States
(12) Patent Application Publication
(10) Pub. No.: US 2007/0026682 A1
(43) Pub. Date: Feb. 1, 2007

(54) Method for advanced time-multiplexed etching

(76) Inventors: Michael J. Hochberg, Pasadena, CA (US); Tom Baehr-Jones, Pasadena, CA (US); Axel Scherer, Laguna Beach, CA (US)

Correspondence Address: Daniel L. Dawes;Myers Dawes Andras & Sherman LLP, Suite 1150, 19900 MacArthur Boulevard, Irvine, CA, 92612, US

(21) Appl. No.: 11/349,865

(22) Filed: Feb. 8, 2006

Related U.S. Application Data
(60) Provisional application No. 60/651,821, filed on Feb. 10, 2005.

(51) Int. Cl. C23F 1/00; H01L 21/302; C03C 15/00

(52) U.S. Cl. 438/710; 438/706; 438/733; 216/67; 216/41

(57) ABSTRACT

A method of anisotropic plasma etching of a substrate material through a window defined in an etching mask comprises the steps of: disposing a hard mask material by injection of a precursor gas or precursor liquid and plasma-activated deposition to form a hard mask layer to form a temporary etch stop on the etching mask; anisotropically plasma etching the hard mask layer by contact with a reactive etching gas to leave a portion of the hard mask layer on vertical walls of the window in the etching mask while exposing at least part of the surface of the substrate; and selectively etching material from the substrate underlying the exposed part of the surface while leaving the portion of the hard mask layer on vertical walls of the window in place.

### RELATED APPLICATIONS

The present application is related to U.S. Provisional Patent Application, Ser. No. 60/651,821, filed on Feb. 10, 2005, which is incorporated herein by reference and to which priority is claimed pursuant to 35 USC 119.

### GOVERNMENT SUPPORT

The present application was funded by the Naval Air Warfare Center Aircraft Division under grant no. N00421-02-D-3223 Boeing Subcontract No. KM5270. The U.S. Government has certain rights.

### BACKGROUND OF THE INVENTION

1. Field of the Invention

The invention relates to the field of anisotropically etching structures defined with an etching mask.

2. Description of the Prior Art

Over the last 15 years, a number of companies have offered silicon deep reactive ion etching systems utilizing the “Bosch” or ASE process for etching structures in silicon, such as shown in U.S. Pat. No. 5,501,893 incorporated herein by reference. This process consists of a time-multiplexed etching scheme, consisting of an isotropic polymer deposition, an anisotropic polymer removal, and then a silicon etch step, which is generally isotropic. These steps (the second and third steps are sometimes combined, because the silicon etching step with SF₆ also etches polymer) are then repeated. The times of the various steps are tuned so as to nearly eliminate etching of the mask layer and of the sidewalls, but to allow etching of the trench.

There is a tradeoff in traditional, non-time multiplexed etching, between the speed of an etch and how anisotropic it is, and an ASE process allows the etch of very high aspect ratio microstructures very quickly. Aspect ratios in excess of 30:1 are often achieved and selectivities in excess of 70:1 to resist are often achievable. This is because a fast, isotropic etch step can be used to remove material quickly, while the polymer depositions protect the sidewalls and force the etch to be anisotropic over many steps.

A time-multiplexed etch is allows one to combine the advantages of an isotropic etch with anisotropic profiles. The isotropic etches are generally very fast and very selective, because they can operate using species that react chemically with the substrate. Although the switching of the etch conditions will generally result in a small-scale scalloping on the sidewalls of the etched areas, these can be reduced in scale to below 10 nanometers in modern processes by fast gas switching. Thus, etches can be developed that have (1) extreme selectivity to mask material, (2) high speed and (3) high anisotropy. The process is thus performed with repetitive pulses of plasma gas etches and plasma depositions and is referred to as a time-multiplexed etch.

The Bosch process, which uses a polymer deposition alternated with an SF₆ based etch of silicon in a plasma reactor is well-known. However, it is limited to silicon, because the chemistry relies upon the deposition of a polymer that only stands up to fluorine based chemistry. Fluorine chemistry, while efficient for etching silicon, is not the most efficient chemistry for etching most materials.

### BRIEF SUMMARY OF THE INVENTION

The illustrated embodiment of the invention is distinct from the prior art, like the Bosch process, because it incorporates the deposition of a hard mask material, which makes a time-multiplexed etch usable for generalized substrate materials, rather than only for silicon as is the case for the Bosch process. Generally, a hard mask material is a material which has an inorganic chemical composition, as contrasted with polymers or organic photoresists, which are not hard mask materials.

For example, in the illustrated embodiment the invention is a method of anisotropic plasma etching of a substrate material through a window defined in an etching mask comprising the steps of: (1) depositing a hard mask material by injection of a precursor gas or precursor liquid and plasma-activated deposition to form a hard mask layer to form a temporary etch stop on the etching mask; (2) anisotropically plasma etching the hard mask layer by contact with a reactive etching gas to leave a portion of the hard mask layer on vertical walls of the window in the etching mask while exposing at least part of the surface of the substrate; and (3) selectively etching material from the substrate underlying the exposed part of the surface while leaving the portion of the hard mask layer on vertical walls of the window in place. These steps can be implemented starting with any of the three steps, since this is a cyclical process. The anisotropy of the etch may be determined not only by the directionally dependent chemical affinities of the etch and the material to be etched, but also by the dynamic nature of a plasma etch process in which the impinging ions have a direction, velocity and acceleration. In some instance the anisotropy may be substantially determined only by geometry of the window and dynamic parameters of the plasma etch.

The method may also comprise the foregoing steps with the understanding that the claimed process may begin at the initialization of any of the above disclosed steps following the definition of the window through the etching mask.

The method further comprises repeating depositing a hard mask material, anisotropically plasma etching the hard mask layer and selectively etching material from the substrate underlying the exposed part of the surface while leaving the portion of the hard mask layer on vertical walls of the window in place.

In the illustrated embodiments the step of anisotropically plasma etching is performed by means of an inductively coupled plasma (ICP) reactive ion etch, or by a conventional reactive ion etch in a parallel-plate reactor.

In the illustrated embodiments the step of disposing a hard mask material comprises disposing a metal, silicon dioxide, silicon nitride, silicon oxynitrides, polysilicon, a liquid precursor of the hard mask material, silicon carbide, carbon, graphite, or diamond-like carbon, through plasma-enhanced chemical vapor deposition (PECVD). The step of selectively etching material from the substrate comprises selectively etching silicon, a Group III semiconductor, or a Group V semiconductor using a plasma-based etch.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112. The invention can be better visualized by turning now to the following drawings wherein like elements are referenced by like numerals.

### BRIEF DESCRIPTION OF THE DRAWINGS

FIGS. 1a-1f is a sequence of side cross sectional diagrammatic depictions of the formation of a trench in a substrate using the hard masking layer and etching techniques of the invention.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE PREFERRED EMBODIMENTS

Recently a number of companies, most notably Oxford Instruments, Sentech and STS, have begun to offer inductively coupled plasma, plasma enhanced chemical vapor deposition systems (ICP PECVD). These are apparatus or tools that utilize an inductively coupled remote plasma chamber in order to do plasma enhanced chemical vapor deposition of oxide and nitride layers, as well as diamond like carbon (DLC), oxynitrides, polycrystalline silicon, germanium and silicon-germanium complexes. The potential also exists for the deposition of metals and all of the other materials for which conventional plasma enhanced chemical vapor deposition systems (PECVD) are currently used.

Plasma enhanced CVD (PECVD) uses a plasma or glow discharge with a low pressure gas, to create free electrons which transfer energy into the reactant gases. This allows the substrate to remain at a lower temperature than in other chemical vapor deposition (CVD) processes. A lower substrate temperature is the major advantage of PECVD and provides film deposition methods for substrates that do not have the thermal stability necessary for other processes that require higher temperature conditions. In addition, PECVD can enhance the deposition rate when compared to thermal reactions alone, and produce films of unique compositions and properties.

Also, the systems that are used for conventional PECVD are not compatible with high rate etch processes, in general, because of the relatively low rates of substrate etching that can be achieved in conventional PECVD tools. However, there is no intrinsic limitation of the processes described here to ICP or any other decoupled reactor geometry such as ECR (electron cyclotron resonance). The use of such a reactor is preferred for the processes disclosed herein.

With the new combined ICP PECVD/ICP RIE systems, it becomes possible to construct a system that does both ICP PECVD deposition and ICP etching, since both are plasma processes that can be performed in the same apparatus. The speeds of the current generation of RF matching networks, pumps and mass flow controllers allows for the extremely rapid switching of gas chemistries in a single chamber, with extremely short residence times. This is thus referred to as a pulsed plasma process. This introduces the possibility of creating a time-multiplexed, fast process for etching of non-silicon materials, using hard masks and non-fluorine chemistries.

In the illustrated embodiment we use a time multiplexing scheme to enhance the selectivity of an etch, where the mask layer is formed by ICP PECVD based growth of a hard mask layer 16. The etch step of the substrate 10 is an ICP based etch step, performed in the same chamber. A third anisotropic etch step for removal of the hard mask 16 over the features to be etched can be included as well.

Hard mask materials 16 may include, but are not limited to, metals, silicon nitride, silicon dioxide, silicon oxynitride, poly silicon, and poly germanium. Materials to be etched may include oxides, nitrides, semiconductors, metals, and any other etchable materials.

The condition for this process to work is the existence of a hard mask layer 16 giving a high selectivity for etching of the substrate material 10. The hard mask layer 16 is defined by two conditions. Any mask layer that can be isotropically disposed or deposited on the surface of the substrate 10 is contemplated as being within the scope of the invention. Similarly, the hard mask layer 16 must be associated with a corresponding anisotropic etch chemistry for the mask material.

An example of such a system is silicon as a substrate 10 and silicon dioxide as a mask material 16, using fluorinated gasses (C₄F₈) to etch the mask 16 and either Cl or SF₆ to etch the substrate 10. Another example is a polymer substrate 10 with silicon dioxide or nitride as a mask material. A third example is silicon dioxide as a material for substrate 10 with metal, e.g. chrome, or aluminum, PECVD'ed as the etch mask 16.

Any material system where a mask material 16 can be deposited in a highly isotropic manner, where there exists a highly anisotropic etch achievable in an ICP reactor for that material 16, and where there is an etch with a high selectivity between said mask material 16 and the substrate material 10, either an isotropic or anisotropic etch, is a candidate for the etching strategy of the invention. There is an extensive literature on various etching chemistries and selectivity information to various mask material, all of which is contemplated as being within the scope of the spirit and teachings of the invention. The claims are thus not to be understood a necessarily limited to the given illustrated embodiments.

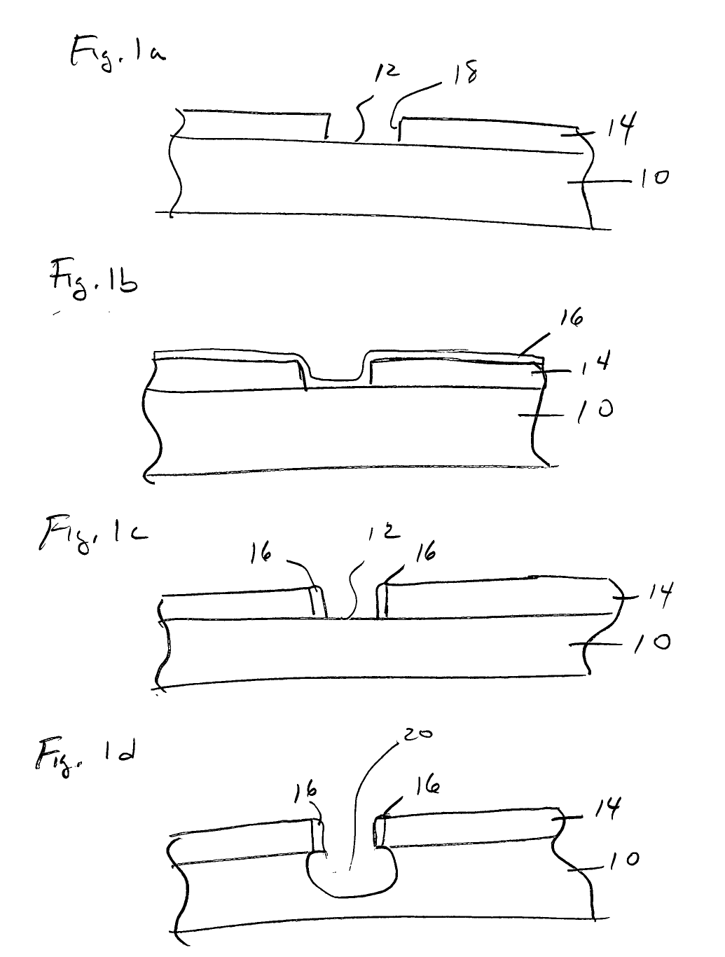

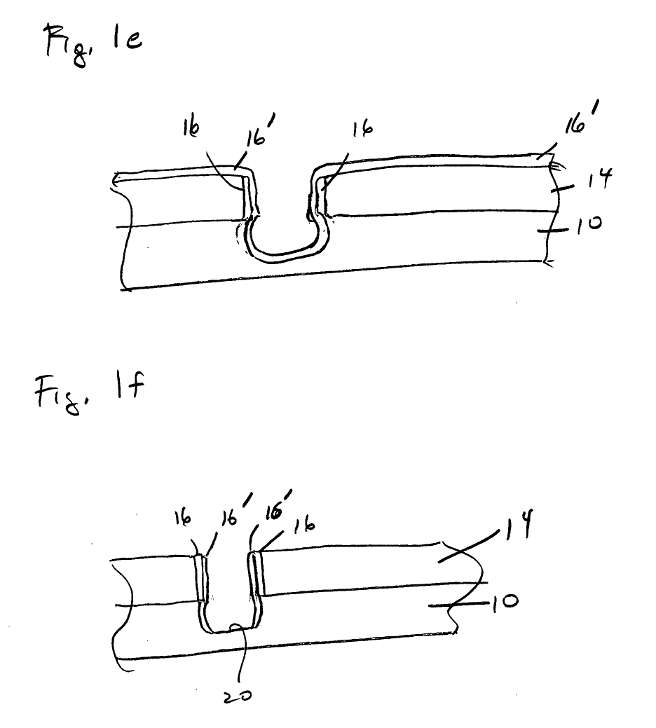

Thus, the illustrated embodiments explicitly include a method of anisotropic plasma etching of an arbitrary substrate material to provide laterally defined recess structures therein through an etching mask employing a plasma as illustrated diagrammatically in FIGS. 1a-1d. The method comprises the steps of anisotropic plasma etching the surface of the substrate material 10 by contact with a reactive etching plasma to remove material 14 from the surface 12 of the substrate material 10 and to provide exposed surfaces 12 as shown in the side cross-sectional view of FIG. 1a. Next as shown in FIG. 1b a hard mask material 16 is disposed or deposited onto surface 12 and material 14 through injection of a precursor gas or liquid and plasma-activated deposition to form a hard mask layer 16 which provides a temporary etch stop. Anisotropic etching of layer 16 occurs as shown in FIG. 1c leaving at least a portion of layer 16 on the vertical walls 18 defined in openings in material 14. Anisotropic plasma etching of material 10 through exposed surface 12 is performed as depicted in FIG. 1d.

The steps of depositing a hard mask material 16 and then subsequent depositions 16′ and anisotropic plasma etching are then repeated in any order any many times as desired, repeating the sequence of steps from FIG. 1b to FIG. 1d, thereby deepening trench 20 as indicated in FIG. 1f. The thickness of layers 16 and 16′ in FIG. 1f on walls 18 has been exaggerated in the figures for ease of visualization, but in the actual instance the thickness of layers 16 and 16′ are such that stepped nature of walls 18 or trench 20 is minimal. According to the preferred embodiments the process may begin after the completion of the step shown in FIG. 1a where the window 12 is defined, after the completion of the step shown in FIG. 1d where the trench 20 is created, or after the completion of the step shown in FIG. 1f where the trench 20 has been deepened. Similarly, substrate 10 may be subjected to an additional conventional etching step where a window 12 is defined and substrate 10 exposed, such as after the completion of any of the steps illustrated in FIGS. 1a, 1c, 1d or 1f.

In the illustrated embodiment the plasma is generated in an inductively coupled reactor. The deposition step is performed with a conventional PECVD reaction. In particular the deposition step is performed with an ICP PECVD reactor.

In one embodiment the deposited material 16 is a metal, silicon dioxide, silicon nitride, silicon oxynitrides, polysilicon, a liquid precursor, such as tetra ethyl ortho silicate (TEOS) or borophosphosilicate glass (BPSG), silicon carbide, carbon, graphite, or diamond like carbon. The substrate material 10 is silicon, a Group III or V semiconductor, such as gallium arsenide, indium phosphide, gallium nitride, or gallium phosphode.

An illustrative listing of substrates, substrate etchants and hard mask materials is given below in Table 1, which is not exhaustive nor limiting of the scope of the invention. For each of the combinations listed in Table 1, the hard mask materials work well as masks for plasma etching as disclosed above. Further, the chemistries in the combinations provide high rate and high selectivity isotropic etching.

TABLE 1

| Substrate | Substrate Etch | Hard Mask |
|---|---|---|
| GaAs | Cl/Ar, BCl₃/Ar, SiCl₄/Ar | SiO₂, SiN, Cr, Ni |
| AlAs | Cl/Ar, BCl₃/Ar, SiCl₄/Ar | SiO₂, SiN, Cr, Ni |
| InGaAsP | Cl/Ar, H₂/CH₄, Hl/Cl₂/Ar, | SiO₂, SiN, Cr, Ni |
| | HBr/Ar | |
| ZnSe | Cl/Ar, BCl₃/Ar | SiO₂, SiN, Cr, Ni |
| GaN | Cl/Ar, Cl/Xe, BCl₃/Ar | SiO₂, SiN, Cr, Ni |
| InGaN | Cl/Ar, Cl/Xe, BCl₃/Ar | SiO₂, SiN, Cr, Ni |
| C (diamond and DLC) | O₂, NO₂ | metals, SiO₂, SiN |
| SiC | CHF₃, C₂F₆, C4F₈ | Al, Ni, Cr |
| SiN | CHF₃, C₂F₆, C4F₈ | Al, Ni, Cr |
| SiO₂ | CHF₃, C₂F₆, C4F₈ | Al, Ni, Cr |
| GaSb | Cl/Ar, BCl₃/Ar, SiCl₄/Ar | SiO₂, SiN, Cr, Ni |
| LiNbO₅ | Cl/CHF₃/Ar | Cr, Ni |
| W | CF₄, CHF₃, C₂F₆, C₄F₈ | Cr, Ni Al |
| Mo | ClF₃ | Ni, Cr |
| Al | BCl₃, Cl/Ar | SiO₂, SiN, Cr, Ni |

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following invention and its various embodiments.

For example, instead of PCP PECVD being used for the deposition step, it is also possible to practice the invention using atomic layer deposition (ALD). Atomic layer deposition (ALD), originally known as atomic layer epitaxy (ALE), is an advanced form of vapor deposition. ALD processes are based on sequential self-saturated surface reactions. Examples of these processes are described in detail in U.S. Pat. Nos. 4,058,430 and 5,711,811 incorporated herein by reference. The deposition processes benefit from the usage of inert carrier and purging gases, which make the system fast. Due to the self-saturating nature of the process, ALD enables almost perfectly conformal deposition of films on an atomically thin level. The technology was initially developed for manufacturing thin film structures for electroluminescent flat panel displays and for conformal coating of chemical catalysts that desirably exhibited extremely high surface area. More recently, ALD has found application in the fabrication of integrated circuits. The extraordinary conformality and control made possible by the technology lends itself well to the increasingly scaled-down dimensions demanded of state-of-the-art semiconductor processing. A method for depositing thin films on sensitive surfaces by ALD is described in WO 01/29839. In addition, ALD can easily be performed in-situ within the same plasma reactor as an ICP deposition process.

Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations. A teaching that two elements are combined in a claimed combination is further to be understood as also allowing for a claimed combination in which the two elements are not combined with each other, but may be used alone or combined in other combinations. The excision of any disclosed element of the invention is explicitly contemplated as within the scope of the invention.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

We claim:

1. A method of anisotropic plasma etching of a substrate material comprising
etching a first mask disposed on a surface of the substrate to define window through the first mask to a portion of the surface of the substrate;
disposing a hard mask material to form a temporary etch stop on the first mask;
anisotropically plasma etching the hard mask layer by contact with a reactive etching plasma or gas to leave a portion of the hard mask layer on vertical walls of the window in the first mask while exposing at least part of the surface of the substrate in the window;
selectively etching material from the substrate underlying the exposed part of the surface in the window while leaving the portion of the hard mask layer on vertical walls of the window in place; and
repeating disposing a hard mask material, anisotropically plasma etching the hard mask layer and selectively etching material from the substrate underlying the exposed part of the surface while leaving the portion of the hard mask layer on vertical walls of the window in place.

2. The method of claim 1 further comprising etching the substrate when the window is defined and substrate exposed.

3. The method of claim 1 where anisotropic plasma etching is performed by means of an inductively coupled plasma (ICP) reaction.

4. The method of claim 1 where disposing a hard mask material comprises disposing a hard mask material by injection of a precursor gas or precursor liquid and plasma-activated deposition to form a hard mask layer by means of a plasma enhanced chemical vapor deposition (PECVD) reaction.

5. The method of claim 1 where disposing a hard mask material comprises disposing a hard mask material by injection of a precursor gas or precursor liquid and plasma-activated deposition to form a hard mask layer by means of an ICP-PECVD reaction.

6. The method of claim 1 where disposing a hard mask material comprises disposing a metal.

7. The method of claim 1 where disposing a hard mask material comprises disposing silicon dioxide, silicon nitride, or silicon oxynitrides.

8. The method of claim 1 where disposing a hard mask material comprises disposing polysilicon.

9. The method of claim 1 where disposing a hard mask material comprises depositing a hard mask material from a liquid source.

10. The method of claim 8 where disposing a liquid precursor of the hard mask material comprises disposing TEOS or BPSG.

11. The method of claim 1 where disposing a hard mask material comprises disposing silicon carbide.

12. The method of claim 1 where disposing a hard mask material comprises disposing carbon, graphite, or diamond-like carbon.

13. The method of claim 1 where selectively etching material from the substrate comprises selectively etching silicon.

14. The method of claim 1 where selectively etching material from the substrate comprises selectively etching a Group III semiconductor, or a Group V semiconductor.

15. The method of claim 14 where selectively etching a Group III-V semiconductor comprises selectively etching gallium arsenide, indium phosphide, gallium nitride, or gallium phosphode.

16. A method of anisotropic plasma etching of a substrate material through a window defined in an etching mask comprising:
disposing a hard mask material by injection of a precursor gas or precursor liquid and plasma-activated deposition to form a hard mask layer to form a temporary etch stop on the etching mask;
anisotropically plasma etching the hard mask layer by contact with a reactive etching gas to leave a portion of the hard mask layer on vertical walls of the window in the etching mask while exposing at least part of the surface of the substrate; and
selectively etching material from the substrate underlying the exposed part of the surface while leaving the portion of the hard mask layer on vertical walls of the window in place.

17. The method of claim 16 further comprising etching the substrate when the window is defined and the substrate exposed.

18. The method of claim 16 further comprising repeating disposing a hard mask material, anisotropically plasma etching the hard mask layer and selectively etching material from the substrate underlying the exposed part of the surface while leaving the portion of the hard mask layer on vertical walls of the window in place.

19. The method of claim 16 where anisotropically plasma etching is performed by means of an inductively coupled plasma (ICP) reaction.

20. The method of claim 16 where disposing a hard mask material comprises disposing a hard mask material by means of a plasma enhanced chemical vapor deposition (PECVD) reaction.

21. The method of claim 16 where disposing a hard mask material comprises disposing a hard mask material by means of an ICP-PECVD reaction.

22. The method of claim 16 where disposing a hard mask material comprises disposing a metal, silicon dioxide, silicon nitride, silicon oxynitrides, polysilicon, a liquid precursor of the hard mask material, silicon carbide, carbon, graphite, or diamond-like carbon, and where selectively etching material from the substrate comprises selectively etching silicon, a Group III semiconductor, or a Group V semiconductor.
